(19) United States
(12) Patent Application Publication
(10) Pub. No.: US 2011/0304240 A1
(43) Pub. Date: Dec. 15, 2011

(54) HIGH EFFICIENCY PIEZOELECTRIC MICRO-GENERATOR AND ENERGY STORAGE SYSTEM

(75) Inventors: Arieh Meitav, Rishon LeZion (IL); Dan Gelvan, Modi'in (IL)

(73) Assignee: SIRIUS IMPLANTABLE SYSTEMS LTD., D.N. Hefer (IL)

(21) Appl. No.: 13/141,004

(22) PCT Filed: Dec. 21, 2009
(86) PCT No.: PCT/IL2009/001204

§ 371 Date: Aug. 29, 2011

Related U.S. Application Data
(60) Provisional application No. 61/139,606, filed on Dec. 21, 2008.

(51) Int. Cl. H02N 2/18; H01L 41/113

(52) U.S. Cl. 310/319; 310/339

(57) ABSTRACT

This present invention provides a power supply for implanting into a patient's body and providing electricity to a load within the body, said power supply comprising an enclosure; adapted for optimizing an activating force by mechanisms of orienting thereof; the power supply further comprising (a) a piezoelectric micro-generator comprising (b) electrical energy storing means; (c) control unit adapted for managing charging and discharging said storing means said control unit further provided with means for decoupling said piezoelectric element from and connecting to said electrical energy storing means to increase efficiency of said power supply.

### FIELD OF INVENTION

The invention relates to a method for making a self-contained renewable power source comprising a power generation unit harnessing external motion and exploiting the corresponding mechanical energy to generate electrical energy, an energy management unit that rectifies the generated AC electrical energy and manages its storage and utilization, and a specialized energy storing element which stores the energy and delivers it subsequently, upon demand.

Components comprising the micro-generator unit are contained within a preferably hermetically sealed enclosure attached, anchored or secured to a moving body that imparts the motion to the enclosure and consequently to the motion harnessing element and the contained piezoelectric element. The enclosure containing the piezoelectric element and the motion harnessing element, constituting a part of the invented device, is set in motion by implanting and affixing the invented device to a moving body like a heart, or other in-body moving organs, or more generally attaching the device on the interior or exterior of a moving mammal or vehicle or other moving or vibrating object providing activation to the harnessing element.

The activation is applied to a cantilever, or strip, bending-type piezoelectric element or any other shape susceptible to bending and/or flexing thereby causing displacement and/or deformation of the element and resulting in the generation of electrical energy. In particular, the invention discloses specific constructions of the piezoelectric element that optimizes it's efficiency as a generator under conditions of low and variable activation force, limited space, for general use and for an implantable device in particular that operates preferably at almost constant and relatively low temperatures, and at low and variable frequency. The invention relates to special designs leading to decreased structural stiffness and increased piezoelectric capacitance. Minimizing the stiffness is of primary importance since it enables lowering of resonance frequency, decreases mechanical damping and enables use of minimal activation force. Both the reduced stiffness and the increased capacitance result in extensive gains in conversion efficiency of the mechanical to electrical energy of the piezoelectric element(s) and increases the overall energy output, while rendering the operation at low frequencies, in the range of a few cycles per second to a few seconds per cycle, more effective.

The inventions relates also to the design of the piezoelectric holding fixture enabling three-dimensional (3-D) activation of the piezoelectric bending element, regardless the orientation of the enclosure relative to the gravitation forces.

The current invention further discloses a method enabling efficient transfer of the electrical energy generated through flexing of the piezoelectric element(s), to the energy storage unit using an energy management unit that rectifies the generated AC electrical energy and manages its storage and utilization, and a specialized energy storing element which stores the energy and delivers it subsequently, upon demand.

### BACKGROUND OF INVENTION

Modern medical science employs numerous electrically powered devices which are implanted in a living body. For example, such devices may be employed to deliver medications, to support blood circulation as in a cardiac pacemaker or artificial heart, a drug pump and the like. Most implantable devices contain primary batteries which have a limited lifetime, contain active chemicals imposing stringent sealing techniques and occupy substantial volume and weight. In some cases rechargeable batteries are used and recharged by transcutaneous induction of electromagnetic fields in implanted coils connected to the batteries or by ultrasonic means. Transcutaneous inductive recharging of batteries in implanted devices is disclosed for example in U.S. Pat. Nos. 3,923,060; 4,082,097; 4,143,661; 4,665,896; 5,279,292; 5,314,453; 5,372,605, and many others.

Due to practical limitation of batteries, a number of implanted devices powered without batteries have been proposed. A variety of techniques based on mechanical and hydraulic principles to harness the physical motion of a heart or other in-body moving organs, to generate electrical energy for pacing, or other electronic implants are disclosed: U.S. Pat. No. 3,486,506, December 1969, and U.S. Pat. No. 3,554,199, January 1971 disclose a cardiac pacemaker that includes a balance wheel driven by heart motion. The balance wheel is coupled to a magnet rotor to induce electric pulses in a stator coil. U.S. Pat. No. 3,563,245, February 1971 discloses a pressure actuated electrical energy generating unit. A pressurized gas containing bulb is inserted into the heart whereby the contractions of the heart exert pressure on the bulb and cause the pressure within the bulb to operate bellows remotely positioned with respect to the heart. The bellows in turn operate an electrical-mechanical transducer. U.S. Pat. No. 3,693,625, September 1972 discloses a device for supplying electrical energy to a heart stimulator placed within the human body in close proximity to the heart muscle. The generator contains a rotor coupled to magnet and induction coil, the rotor being driven by fluid contained within two elastic bags periodically contracted through heart motion thereby pushing the liquid from bag to bag via piston chambers that drive the rotor. U.S. Pat. No. 3,826,265, July 1974 discloses mechanical pulse generator for cardiac pacing. The generator is composed of a harnessing mechanism containing bladder, fluid, bellows or spring to transfer the motion to a torsion spring coupled to a shaft and induction coil. U.S. Pat. No. 3,906,960, September 1975 discloses energy converter integrated into a pacemaker electrode implantable in a vessel or heart ventricle or in muscle, with gas filled and sealed housing. Electricity generation is based on activation of a bi-stable magnet spring system, integrated with a reluctance generator and an energy storage element. U.S. Pat. No. 5,810,015, September 1998 discloses a power supply for implantable devices, activated by mechanical, chemical, thermal, or nuclear energy into electrical energy. The invention provides a method of supplying energy to an electrical device within a mammalian body in which the mammal is implanted with an apparatus including a power supply capable of converting non-electrical energy into electrical energy and the non-electrical energy is transcutaneously applied to the apparatus.

The utilization of piezoelectric materials as actuators and sensors is increasing. Miniaturized power sources for MEMS and microelectronics are in growing demand. Combining the needs for Miniaturization with the extremely low-power consumption of the newly emerging microelectronic technologies leads to increased interest in piezoelectric materials as micro-generators. The use of piezoelectric materials yields significant advantages for micro-power systems. The energy density achievable with piezoelectric devices is potentially greater than that possible with electrostatic of electromagnetic designs. Also, the fact that piezoelectric elements are not affected by external magnetic fields is specifically important feature in the case of implantable devices. Since piezoelectric elements convert mechanical energy into electrical energy via strain, or stress, with displacements in the range of microns, they have an inherent advantage in miniaturization. The absence of active chemicals like those contained in batteries, eliminates the need for specific sealing means, and eliminates the limit on life-time. Piezoelectric benders have proven themselves reliable for 10⁹ cycles and more.

Harnessing mechanical motion to activate piezoelectric element thereby producing electrical energy has been disclosed in variety of patents: U.S. Pat. No. 5,751,091, May 1998, discloses a piezoelectric power generator for a portable power supply and portable electronic applications. U.S. Pat. No. 5,835,996, November 1998 discloses a power generator using a piezoelectric element with specific parameters of the activation displacement providing high efficiency of power generation. The patent points out the function of the ratio of the initial unloaded voltage value of the piezoelectric to a prescribed output voltage of the piezoelectric. The practically preferred ratio of the piezoelectric Open Circuit Voltage to Load Voltage is claimed to be in a quite wide range of approximately two to twenty. US Patent Application 20040212280, October 2004 discloses a force-activated electrical power generator using piezoelectric elements with specific rectification, filtering and other conditioning components. US Patent Application 20050082949, April, 2005 discloses a stacked multilayer piezoelectric element attached to a mechanical device providing deformation of the piezoelectric element. US Patent Application 20050225207, October 2005 refers to a belt piezoelectric generator generating continuous alternate current by mechanically moving a multi-electrode piezoelectric endless ceramic belt between two rows of rollers so that the belt forms a wavy shape Piezoelectric. US Patent Application 20050280334, December 2005 discloses a piezoelectric power generator comprising plural piezoelectric devices arranged in circular patterns and activated by a rotating actuator. The resultant AC voltage is rectified and utilized to charge battery or capacitor. US Patent Application 20050288716, December 2005 discloses a piezoelectric acupuncture device, applied externally to chest of a patient whose heart is in cardiac arrest for restoring normal contraction rhythms of a heart, or for pacing a heart. The piezoelectric activation is conducted manually. US Patent Application 20050269907, December 2005 refers to a power generator employing piezoelectric materials.

As shown above, the use of piezoelectric elements in implantable devices as sensors or power generators has been disclosed in several publications and patents. In general three basic principles of piezoelectric deformation-activation are disclosed: (a) Kinetic activation where the piezoelectric element is affixed to the moving organ, like the heart, in such a manner that it is flexed through heart contraction and expansion; (b) inertial activation where a ballast weight is attached to the piezoelectric element and (c) Transcutaneous activation, through applying ultrasonic energy by an external transmitter to set the piezoelectric element in motion such that it may be used as a sensor, actuator or a micro-generator.

Utilization of piezoelectric material in the form of foils or bands wrapped around a patient's chest or leg for measuring heart beats and blood flow has been suggested by E. Hausler et all in IEEE 1980 Biomedical Group Annual Conference, Frontiers of Engineering in Health Care, and by Michael A. Marcus in Ferroelectrics, 40 1982, “Ferroelectric Polymers and their Application”. In 1984 Haustler et all proposed a power supply based on PVDF (polyvinylidene fluoride) piezoelectric that could be surgically implanted in an animal to convert mechanical work done by a dogs' breathing into electrical energy, Ferroelectronics, 60, 277, “Implantable physiological power supply with PVDF film”.

U.S. Pat. No. 3,456,134, July 1969 discloses an encapsulated cantilevered beam composed of a piezoelectric crystal mounted in a metal, glass or plastic container and arranged such that the cantilevered beam will swing in response to movement. The cantilevered beam is further designed to resonate at a suitable frequency and thereby generate electrical voltage. U.S. Pat. No. 3,659,615, May 1972 discloses a piezoelectric bimorph encapsulated and implanted adjacent to the left ventricle of the heart and arranged to flex in reaction to muscular movement to generate electrical power. U.S. Pat. No. 4,140,132, February 1979 discloses a cantilever piezoelectric crystal mounted within an artificial pacemaker can having a weight on one end, and constructed to vibrate to generate pulses which are a function of physical activity. U.S. Pat. No. 4,690,143, September 1987 claims a pacing lead with a piezoelectric device included in a catheter distal end portion with a piezoelectric device and is adapted to be inserted into a human heart. The piezoelectric device is designed to generate electrical energy in response to movement of the implanted pacing lead upon contraction of the heart. The device can be made of a ceramic bimorph or a PVDF film. U.S. Pat. No. 5,431,694, July 1995 discloses a piezoelectric generator in the form of a flexible sheet of poled PDVF which while being bent generates an electrical current to charge the storage device. The generator is adaptable to be attached to a structure which can repetitively bend it, and to generate an electrical current while being bent. The bending action is provided by the heart muscle, by lung expansion or bending of a rib, as examples. The storage device is adapted to be connected to a user device such as a pacemaker. U.S. Pat. No. 6,654,638, November 2003 discloses an implantable, ultrasonically activated piezoelectric element receiving the mechanical energy for activation from a source external to the implantable electrode. US Patent Application 20050027323; February 2005 discloses an implantable medical device utilizing a piezoelectric crystal for monitoring signs of acute or chronic cardiac heart failure by measuring cardiac blood pressure and mechanical dimensions of the heart and providing multi-chamber pacing. The sensor comprise at least two sono-micrometer piezoelectric crystals, one serving an ultrasound transmitter when a drive signal is applied to it and the second, attached to a second lead body implanted into or in relation to a second heart chamber that operates as an ultrasound receiver. US Patent Application 20050052097, March 2005 claims for a piezoelectric power generation system which performs a highly efficient power generation using a piezoelectric element without dependency on the direction of an externally driven vibration. The system includes a vibrator having a cantilever beam in the form of a rod and an impact element such as a steel ball. The dependency on the vibration direction in the vibrator is minimized to improve the efficiency of power generation.

### SUMMARY OF THE INVENTION

The disclosed piezoelectric micro-generator is intended to generate maximal electrical energy with minimal activation force, at low frequency and small size of the piezoelectric element and to provide most effective architecture with respect to size and transformation efficiency.

The disclosed micro-generator is adapted to pick up external motion and convert the aforesaid motion into electrical impulses by means of an oscillating piezoelectric element. The aforesaid piezoelectric element is provided with a mechanical harnessing unit inertially affecting the piezoelectric element. It should be appreciated that the harnessing unit is exposed to an externally applied force caused by the patient's body or a specific organ and gravitation force. Efficiency of the piezoelectric conversion of mechanical energy can be performed due to orienting the piezoelectric element optimally to the applied forces. In accordance with one embodiment of the current invention, the proposed device comprises a gyro system adapted to optimally orient the piezoelectric element.

The micro-generator further comprises a power control unit which manages providing electrical energy generated by the piezoelectric element to the energy storage unit. The power control unit is adapted to decouple the piezoelectric element from the energy storage unit and to ensure energy transformation according to present conditions ensuring optimal trade-off.

It is hence one object of the invention to disclose a power supply for implanting into a patient's body and providing electricity to a load within the body. The aforesaid power supply comprises an enclosure which is adapted for optimizing an activating force by means of orienting thereof; the power supply further comprises
(a) a piezoelectric micro-generator comprising
(i) a piezoelectric element/having an elongate shape with first and second terminals; said first terminal mechanically connected to said enclosure; said piezoelectric element configured for substantially resonant oscillation at frequency characterizing motion of said patient's heart or other organ;
(ii) a mechanical harnessing unit mechanically connected to said second terminal of said piezoelectric element to increase an oscillation amplitude of said piezoelectric element;
(b) electrical energy storing means;
(c) control unit adapted for managing charging and discharging said storing means

The control unit is further provided with means for decoupling the piezoelectric element from and connecting to the electrical energy storing means to increase efficiency of the power supply.

Heart, limb and any other moving parts and organs of patient's are in the scope of the current invention.

When the proposed device is attached to the cardiac muscle, contractions thereof cause device displacement. The mechanical harnessing unit inertially affects the piezoelectric element, specifically, that causes oscillation of the piezoelectric element.

Another object of the invention is to disclose the piezoelectric element configured as a laterally bending cantilever.??

A further object of the invention is to disclose the generator comprising a power control unit adapted to effectively convert electrical oscillations of ultralow frequency created in the piezoelectric element between activation events.

A further object of the invention is to disclose the power control unit adapted to accumulate energy of activation impulses independently of repetition rate thereof. variations in ??

A further object of the invention is to disclose the power control unit adapted to compensate differences between condition of physical activity and rest.

A further object of the invention is to disclose the power control unit adapted to perform at least one function selected from the group consisting of voltage rectification, the storage unit, providing stored electricity to the load and any combination thereof. Decoupling? Controlling? Switching>

A further object of the invention is to disclose the electrical energy storage comprising an array of storing elements.

A further object of the invention is to disclose the electrical energy storage comprising at least one capacitor.

A further object of the invention is to disclose the electrical energy storage comprising at least one rechargeable battery.

A further object of the invention is to disclose the piezoelectric element configured for substantially resonant oscillation with a frequency ranged between about 1 and 3 Hz.

A further object of the invention is to disclose the piezoelectric element which is made of PZT ceramics.

A further object of the invention is to disclose the piezoelectric element configured as a multilayer structure (a piezoelectric stack).

A further object of the invention is to disclose the piezoelectric stack comprising at least one inactive layer adapted to strengthen the stack while minimally impeding the optimize elasticity thereof.

A further object of the invention is to disclose the piezoelectric element disposed in a holder which is adapted for linear displacement along an axis of the piezoelectric element, angular displacements around the axis of the piezoelectric element and in a plane of the piezoelectric element to orient the piezoelectric element perpendicularly to the activating force.

A further object of the invention is to disclose a method of piezoelectric conversion of a patient's body motion into electrical energy. The aforethe method comprising the steps of: (a) providing a micro-generator further comprising (i) a enclosure; (ii) a piezoelectric element having an elongate shape with first and second terminals; the first terminal mechanically connected to the enclosure; the piezoelectric element configured for substantially resonant oscillation at frequency characterizing motion of the patient's body; and (iii) an electric energy storing means; (b) implanting into the patient's body; and (c) inertially picking up mechanical energy of body motion.??

It is a core purpose of the invention to provide the step of picking up mechanical energy performed by the piezoelectric element provided at the second terminal with a mechanical harnessing unit to increase oscillation amplitude of the piezoelectric element.???

A further object of the invention is to disclose the method further comprising a step of effectively converting electrical oscillations of ultralow frequency created in the piezoelectric element between activation events.

A further object of the invention is to disclose the method further comprising a step of compensating the beat to beat variation in frequency and activation force.

A further object of the invention is to disclose the method further comprising a step of accumulate energy of activation impulses independently of variations in ??repetition rate thereof.

A further object of the invention is to disclose the method further comprising a step of performing at least one function selected from the group consisting of voltage rectification, charging the storage unit, providing stored electricity to the load and any combination thereof. See above

A further object of the invention is to disclose the method further comprising a step of linearly displacing the piezoelectric element along an axis thereof, angularly displacing of around the axis of the piezoelectric element and in a plane of the piezoelectric element to orient the piezoelectric element perpendicularly to an activating force.

### BRIEF DESCRIPTION OF THE DRAWINGS

In order to understand the invention and to see how it may be implemented in practice, a plurality of embodiments is adapted to now be described, by way of non-limiting example only, with reference to the accompanying drawings, in which

FIGS. 1a and 1b are schematic views of coin and prismatic embodiments of the piezoelectric generator, respectively;

FIGS. 2a and 2a are schematic views of the unimorphic cantilever bender in balanced and loaded positions;

FIG. 3 is an electric diagram of the bimorph cantilever bender;

FIG. 4 is an electric diagram of the monoblock cantilever bender;

FIGS. 5a and 5b are electric diagrams of the parallel and series cantilever generator, respectively;

FIGS. 6 and 7 are temperature dependences of the ratio and compound of piezoelectric voltage and strain constants d₃₁ and g₃₁, respectively;

FIGS. 8a-8e are schematic diagrams of angular and linear motions of the piezoelectric element,

FIG. 9a is a time curve of the cardiac acceleration;

FIG. 9b is a time curve of the piezoelectrically generated voltage;

FIG. 10a is a geometric scheme of the micro-generator orientation relative to the heart; and

FIG. 10b is a graph of the generated voltage in dependence on the geometric orientation.

### DETAILED DESCRIPTION OF THE INVENTION

The following description is provided, alongside all chapters of the present invention, so as to enable any person skilled in the art to make use of said invention and sets forth the best modes contemplated by the inventor of carrying out this invention. Various modifications, however, are adapted to remain apparent to those skilled in the art, since the generic principles of the present invention have been defined specifically to provide a piezoelectric micro-generator.

The components comprising the piezoelectric micro-generator device include: (a) Enclosure—can anchored to the moving body and including the parts comprising the micro-generator. (b) Harnessing mechanism—mechanism trapping and transforming the motion of the enclosure to impart deflection/deformation to the piezoelectric element; (c) piezoelectric element—element converting the mechanical motion of displacement/distortion to electrical energy; (d) charging power management—unit rectifying the AC output of the piezoelectric to DC voltage and controlling the transmission of the electrical energy generated by the piezoelectric element to the energy storage unit; (e) energy storage—unit charged by the piezoelectric, through the charging power management unit; (f) delivery power management—unit controlling the delivered energy from the energy storage unit to the external load. In practical terms, the charging power management and the delivery power management may be designed as a single IC unit maintaining both functions; (g) Electrodes—electrodes associated with the enclosure can and providing the output energy from the energy storage unit to the external load.

As described above, conversion of the exterior motion to electrical energy stored by the energy storage unit takes place via several steps, each step being associated with corresponding efficiency. (1) Harnessing efficiency—defining the extent the harnessing mechanism succeeds to trap the exterior motion and convey it to the piezoelectric element; (2) Conversion efficiency—defining the extent to which the mechanical energy applied on the piezoelectric element and causing its' deformation is converted to electrical energy generated by the piezoelectric element at open circuit conditions; (3) Transformation efficiency—defining the extent to which the electrical energy generated at the piezoelectric element is transformed to the energy storage unit.

The total efficiency of converting mechanical motion to electrical energy stored at the energy storage unit (battery or capacitor) is the multiplication of all three efficiencies

ηₜ=η₁*η₂*η₃.

In practical applications, limitations of size, activation force and frequency are imparted. To achieve maximal total efficiency imposed by practical conditions, trade-off optimization is unavoidable.

The conversion efficiency of mechanical to electrical energy is a fundamental parameter for the development and optimization of a power generation device and it has been discussed in many publications. All have noted that high efficiency for piezoelectric conversion requires large quality (Q) and electromechanical coupling (k²) factors. However, no work has been conducted to provide optimal conditions upon utilization of miniature piezoelectric elements of less than 50 cubic millimeters, should be activated by minimal force in the range of a few milli-Newton and at low frequency of less than 3 Hz under variable frequency, activation force and motion. It should be noted as well that the maximal conversion efficiency discussed in literature and related to the Q and k² factors is related to piezoelectric at Open Circuit Voltage (OCV) conditions while at practical application the generated energy at OCV has to be utilized to charge the energy storage unit. Furthermore, practically all previous designs have been targeted to perform under stable conditions and at the resonance frequency. However, the present invention addresses conditions typical of biological systems, where the frequency is variable and the activation force and the details of the motion vary from cycle to cycle. Hence, the current invention provides design solutions to the challenge of working at a broader frequency band and under unpredictably variable conditions.

At the other interface of the piezoelectric element, there are also publications discussing the optimal conditions ensuring maximal efficiency to deliver the generated electrical energy from the piezoelectric element to the energy storage unit. However, also here there is no discussion how the outlined optimal parameters should be matched with miniature size of piezoelectric element that are activated by minimal force and operated at low frequency.

This application discloses the design of a piezoelectric element intended to generate maximal electrical energy at OCV with minimal activation force, at low frequency and small size of the piezoelectric element, and an energy storage unit that is specifically designed to match the piezoelectric element of prior application and is designed to fit the special operation and size conditions described above and to provide most effective architecture with respect to size and transformation efficiency.

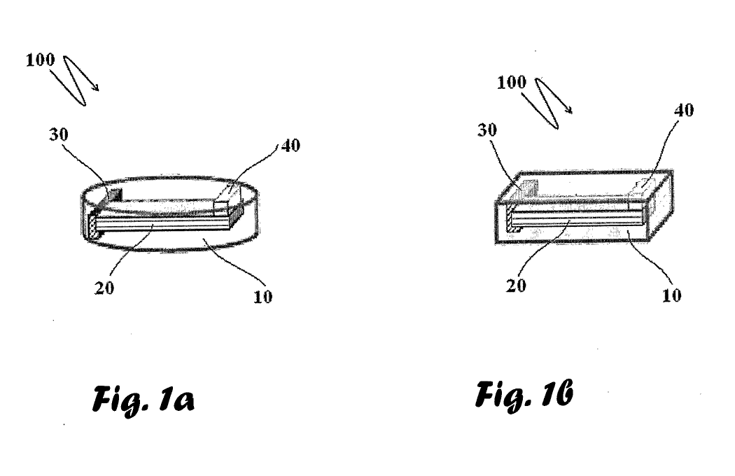

Reference is now made to FIGS. 1a and 1b, presenting a micro-generator 100 of coin and prismatic shapes, respectively, which comprises a housing 10 and a piezoelectric element 20. The piezoelectric element 20, of a cantilever or other shape but still a strip-bending type, held by a holder 30, is activated by a mechanical harnessing unit 40 that is permanently fixed to the piezoelectric activation tip. The piezoelectric element comprises of a mono-block cantilever, each block constructed of a multi-layer stack, each stack containing at least five electrically parallel connected layers, each layer typically 15-20 micron thick. As shall be discussed elsewhere, the thin layers, the parallel connection of the stacked layers and the mono-block piezoelectric design allows the achievement of high piezoelectric capacitance and very low stiffness, enabling piezoelectric displacement-activation by a very small force and piezoelectric vibration flexing at resonance, or close to resonance frequency are critical parameters for achieving maximal power output at minimal activation force and low vibration frequency.

The power control unit takes part in transformation of the generated electrical energy by the piezoelectric to the energy storage unit. The function of this unit is to decouple the piezoelectric element from the energy storage unit and to ensure energy transformation according to present conditions ensuring optimal trade-off. It is a further function of the power control unit to create an ongoing adaptation of the charging link between the piezoelectric element and the appropriate capacitor(s) as the charging conditions change at several levels: 1) the damping in the amplitude of individual self-vibrations of the piezoelectric element that occur between activation events 2) the beat to beat variation in frequency and activation force; 3) the differences between condition of physical activity and rest. The power control unit maintains the functions of voltage rectification, control and switching and it is operated at ultra low power consumption. It is the scope of the current invention to disclose energy storage unit comprised of several independent capacitors switched/coupled to the piezoelectric element in specified sequence by the power management unit. Prevention of permanent parallel contact of the energy storage capacitor to the piezoelectric element ensures high transformation efficiency upon conveying the electrical energy from the piezoelectric element to the energy storage elements.

According to one design of the invention, the same power management unit may serve also to control and switch the output power per output parameters of the algorithm element comprising the power delivery. As to be discussed elsewhere, the efficiency of removing the electrical energy from the piezoelectric element to charge an energy storage element is strongly affected by the relative values of the OCV generated by the piezoelectric deformation and the voltage of the energy storage element that is charged by the piezoelectric through the power control unit. The current invention discloses the proper design parameters to mach the piezoelectric OCV and the voltage of the energy storage element as to ensure utilization of the piezoelectric electrical energy at high efficiency.

The energy storage unit is comprised of several, but at least two, capacitors, each being independently charged by the power control unit. As to be discussed elsewhere, utilization of capacitors provides an inherent advantage over use of rechargeable battery. The type of capacitor and the capacitance value are also key parameters markedly determining the micro-generator performance and shall be discussed in details.

The power delivery unit comprises an algorithm element and it is coupled to the external load by electrodes which extend from the case or comprise an integral part of it. The electrodes provide the electrical connection to the heart. According to one design of the invention, the electrodes also function as attachment of the case to the heart, in such a way that does not restrict their use as voltage terminals to deliver the output power for any external load. In the case of heart pacing, the algorithm element receives the input (sensing) voltage trough the electrodes and determines whether a pulse will be delivered, and creates the appropriate architecture of the capacitor array to deliver the required output voltage amplitude and the width of the delivered pulse. A separate output power control, or single input/output control and switching elements may be used to control and switch the charging and discharging modes of the capacitors. According to the current invention no DC-to-DC converter is necessary to deliver output voltages at variable values, as determined by the algorithmic element. It is the function of the output switching power controller to interconnect the capacitors in single, series, or parallel architectures as to maintain the output voltage levels and stable voltage output at any voltage and pulse width. More details shall be disclosed elsewhere.

Accordingly, it is the scope of the present invention to provide a functionally optimal method of power generation and energy storage, comprising a self-contained micro-generator having a high efficiency of harnessing exterior motion by affixing the micro-generator to a moving body and including a special piezoelectric cantilever to generate electrical energy, and a means of efficient energy storage adapted to the self-contained power generation method and power generator.

Since the external motion may occur in any direction in space, and these directions may vary in relation to the force of gravity, it's the further scope of the invention to describe a special device for holding and orienting the piezoelectric element that is capable of harnessing the external motion regardless the direction of its component vectors in space.

A further objective is to provide coupling of the special design of the piezoelectric element with a special energy storage unit explicitly coupled to the piezoelectric element such as to achieve efficient utilization of the generated energy.

It is an object of the present invention to provide a small size, high performance power generator and energy storage unit. Still other objectives and advantages of the invention will in part be obvious from the detailed specifications to follow. This invention accordingly comprises the several construction and design elements and the relation of one or more of which with respect to each of the others and the apparatus embodying features of construction, combinations of elements and arrangement of parts which are adapted to effect such performance, all as exemplified in the following detailed disclosure and the scope of the invention will be indicated in the claims.

### Description of the Preferred Embodiments

Piezoelectric Element

The design of the PE element of the invention is aimed at achieving several key properties not treated in prior art piezoelectric technology. More specifically, while utilization of piezoelectric technology for actuator and sensor applications has been widely discussed, developed and is at relatively wide use, practical utilization of piezoelectric as power generator is in it's infancy. The basic idea of utilizing the inherent characteristics of piezoelectric materials to harness physical motion, including coupling the piezoelectric to heart has been disclosed in patents and publications listed above. However, none of these deals with detailed design and construction as to meet specific characteristics set forth in the current invention, namely: small-size, lightweight power source and activated through physical motion of the device comprising the piezoelectric element. The scope of the design is to provide power output at high power density while being activated through minimal deflection force that is applied at low frequency of less than 3 Hz, typical for body organs, and in particular 1-3 Hz typical for the beating heart. The key design parameters of the piezoelectric element of the current invention are related to realization of a piezoelectric construct with minimal stiffness and maximal capacitance, both features enabling activation by minimal force, typically of few mN, achievement of low resonant frequency, and enabling the delivery of high electrical energy to charge the energy storage unit.

Referring to the piezoelectric generator element of the present invention the basic design is based on a cantilever, bending type construction. In principle this type of construction is the most effective to enable operation at minimal resonant frequency and minimal damping affect with minimal activation force. Since the primary scope of the invention is harnessing the motion of the heart to utilize the generated energy for a variety of implanted medical devices, including but not limiting, cardiology related applications, the low resonant frequency is important due to the low frequency of heart beats, typically 70-80 bpm (1.2-1.3 Hz), or the even lower frequency of other body organs. Nevertheless, due to the relatively well-defined frequency of the heart, or other body organs, the piezoelectric cantilever could be designed to match the resonant frequency, thereby increasing the overall efficiency. The small activation force is important since the inertial activation is proportional to the inertial mass which is of few grams in general and most preferably of less than half gram. As it shall be ° disclosed in details elsewhere the activation ballast fixed to the flexing tip of the piezoelectric preferably consists of the energy storage unit and the power management unit thereby saving volume and weight.

In particular, decreasing the structural stiffness leads to the largest gains in efficiency, followed by decreasing the mechanical damping and increasing the piezoelectric capacitance.

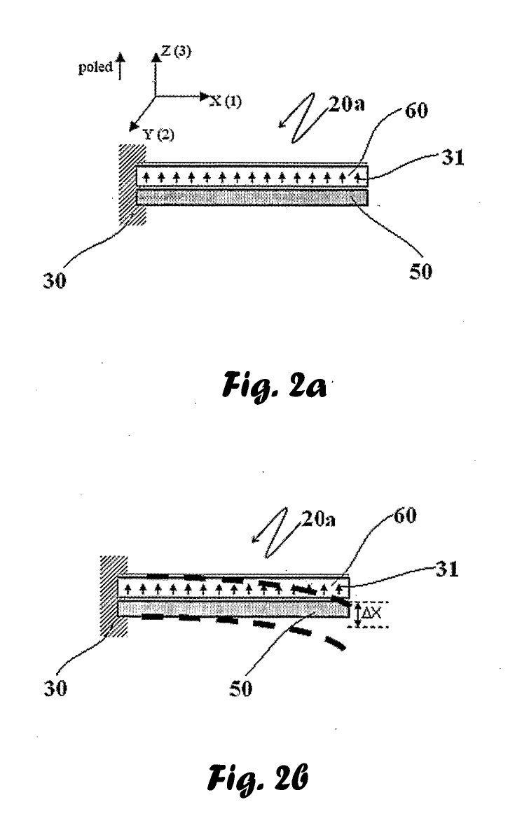

Reference is now made to FIGS. 2a and 2b, presenting a unimorphic cantilever bender 20a in balanced and loaded positions. The unimorphic cantilever bender 20a comprises piezoelectric layer 60 and inactive vane 50. Mechanical deformation of the piezoelectric element causes partial transformation of the mechanical energy to electrical energy, defined theoretically by the electro-mechanical coupling coefficient. The principle of piezoelectric cantilever operation is related to motion that causes the piezoelectric element to expand or contract, the deformation causing charge separation and formation of voltage across the two electrodes of the piezoelectric element, thereby resulting in an apparent charge on the piezoelectric capacitor, to be denoted Cₒ. There are several cantilever constructions all causing piezoelectric longitudinal deformation upon flexing the free tip of the piezoelectric cantilever. In most practical cases of strip-type benders, the poling orientation is perpendicular to the longitudinal axes of the cantilever and the relative orientation of the deformation force applied on the cantilever relative to poling is 31 (FIGS. 2a and 2b). The most simple cantilever construction is a unimorphic where a piezoelectric (poled) layer is applied over an inert layer, forming a double-layer strip, similar to bimetals. When a force is applied on the free flexing tip of the piezoelectric cantilever, the bending leads to expansion of the outer layer, with the higher radius and contraction of inner layer. Thus upon periodic bending of the piezoelectric/metal cantilever the piezoelectric element is periodically stretched and contracted thereby resulting in alternatively charged electrodes across the piezoelectric ceramics, or equivalently periodically charged Cₒ capacitor. At frequencies outside the resonance, piezoelectric ceramic transducers are fundamentally capacitors. Consequently, the voltage coefficients gᵢⱼ are related to the charge coefficients dᵢⱼ by the dielectric constant Kᵢ as, in a capacitor, the voltage V is related to the charge Q by the capacitance C. The equations are:

Q=CV; d₃₁=K₃^{T}ε₀g₃₁;

d₃₃=K₃^{T}ε₀g₃₃; d₁₅=K₁^{T}ε₀g₁₅

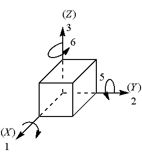

Because of the anisotropic nature of PZT ceramics, piezoelectric effects are dependent on direction. The 1, 2, and 3 indexes correspond to X, Y, Z of the classical right-hand orthogonal axis set). The direction of polarization (axis 3) is established during the poling process. Thus the polar, or 3 axis, is taken parallel to the direction of polarization within the ceramic. This direction is established during manufacturing by a high DC voltage that is applied between a pair of electrodes faces to activate the material. Piezoelectric coefficients with double subscripts link electrical and mechanical quantities. The first subscript gives the direction of the electrical field associated with the voltage applied, or the charge produced. The second subscript gives the direction of the mechanical stress or strain.

At resonance, the dielectric constant will be reduced by the factor (1−k²) where k is the coupling coefficient.

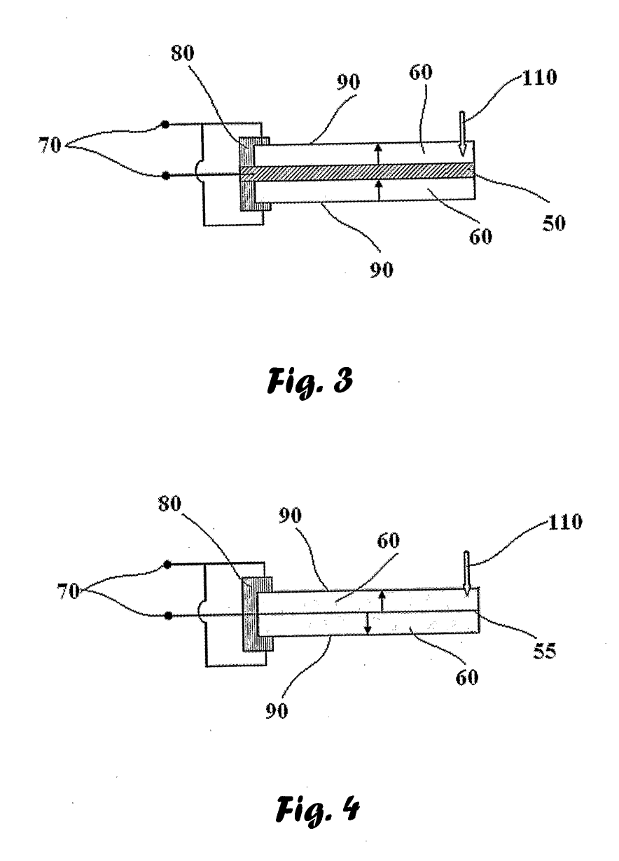

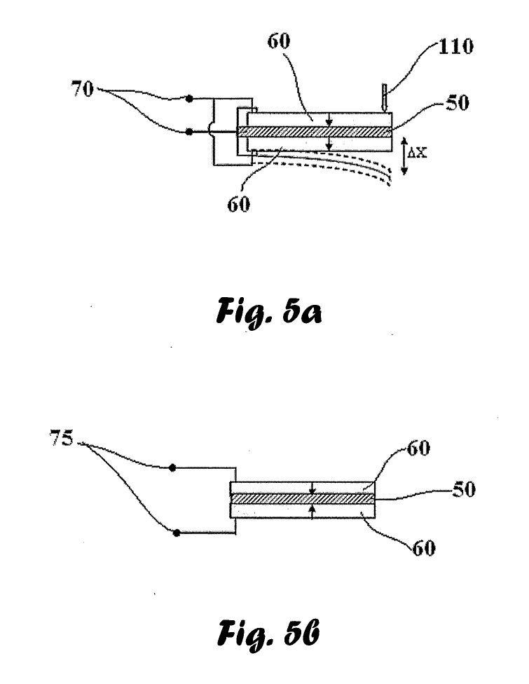

Reference is now made to FIGS. 3 and 4, presenting bi-morph and mono-block cantilever benders, respectively. By combining more than one piezo-layer 60, it becomes possible to further increase the amount of transduction. For instance, a cantilever device can be created by placing two layers 60 of piezoelectric material provided with conducting layers 90 and disposed on alternative side of an inert, non-active support 50 like is illustrated schematically in FIG. 3. Another and more efficient option is excluding the inactive layer and placing two active piezoelectric layers 60 on top of one-another, and by controlling the direction of polarization and the voltages such that when one layer contracts, the other expands (FIG. 4). Exclusion of the inactive layer imparts an important feature to the resultant cantilever: reduction of the stiffness and consequently the accompanying features, as mentioned above. This is the specific design that has been chosen in the current invention as the most effective, however not limiting the other constructions known in the art that may be used while implementing the other supplementary design features to be disclosed herein.

Another modification known in the field is replacing a single piezoelectric layer by several thin layers thereby creating what is known as a piezoelectric stack. Combining thin layers in parallel to form a piezoelectric stack increases the capacitance while still maintaining low deflection force.

The relation of the open circuit voltage (OCV), the Capacitance and the Surface charge of a piezoelectric bi-morph are shown in the following formulae.

Reference is now made to FIGS. 5a and 5b, presenting ceramic layers 60 of the piezoelectric stack can be electrically connected either in series or parallel, respectively. Ceramic polarity of the poling direction and the electrical connections for each of the configurations are shown.

Parallel Connection of PE Layers

Vₒ=¾g₃₁*[F*L/(W*T)]*(1−(t/T)²*A (1a)

Series Connection of PE Layers

Vₒ= 3/2g₃₁*[F*L/(W*T)]*(1−(t/T)²*A (1b)

Q=3F*L²*d₃₁/T² (2)

Cₒ=Q/Vₒ (3)

Cₒ=4W*L*d₃₁/(T*g₃₁) (4)

Where

Vₒ is a generated OCV;

W is a width;

g₃₁ is a PE voltage constant;

L is a length;

F is an applied force;

T—is an overall combined thickness;

t is a vane/epoxy combined thickness;

Q is a charge;

d₃₁ is a PE strain constant

A is an empirical weighing factor;

Cₒ is PE capacitance

It can be seen in equations 1a or 1b that Vₒ may reach maximum when t=0. Thus, reducing the thickness of the inactive vane, or eliminating it, as is in the mono-block design implemented in the current invention, results in maximal value of OCV, while keeping the other parameters constant.

The capacitance of a dielectric can be expressed in the general equation:

Cₒ=εᵣε₀^{x}A/T; (5)

Where εᵣ is the relative dielectric contestant; ε₀ is the dielectric constant of air=8.85×10⁻¹² F/m; A is the capacitor area of the electrodes; T is the thickness of the dielectric material, or the distance between electrodes.

Comparing equations 4 and 5 leads to

d₃₁/g₃₁=εᵣε₀^{x} (6)

The maximal electrical energy of a PE element at a certain cantilever deflection (ΔX) is

Eₒ=½ CV₀² (7)

Where Eₒ is the maximal generated energy through the mechanical deformation at OCV conditions, meaning no current/energy is withdrawn from the piezoelectric construct; C is the piezoelectric capacitance and V₀ is the instantaneous Open Circuit Voltage at deformation/deflection ΔX.

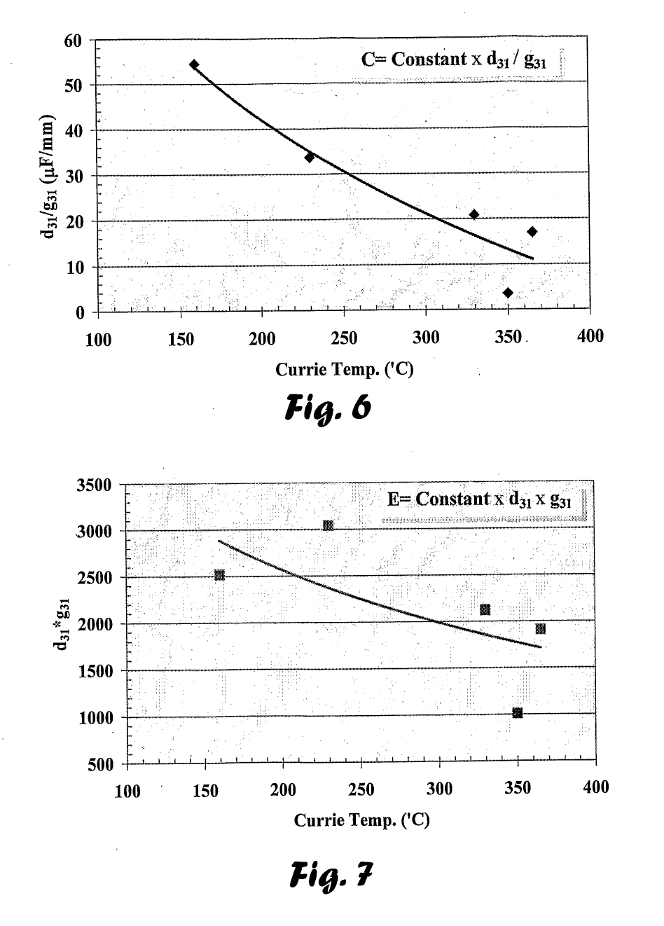

As can be seen in equation 4 maximal capacitance of a piezoelectric element at given dimensions (W, L) is inversely proportional to the thickness of the piezoelectric element (T). Thus, as shall be discussed elsewhere, the approach disclosed in this invention includes utilizing minimal thickness of the piezoelectric. Another parmeter affecting the capacitance is the d₃₁/g₃₁ value. Since current invention relates to implantable applications where the temperature doesn't increase above 42° C., soft piezoelectric materials with low Currie temperature may be used without concern of thermal depolarization. It is within the scope of this invention to make use of the apparent correlation between the value of Currie temperature and the values of the dielectric constant or the strain and voltage constants (d₃₁, g₃₁). Table 1 herein and FIGS. 6 and 7 illustrate the apparent characteristics of some commercial PZT material and they clearly demonstrate the benefits of utilizing materials with lower Currie temperature which have maximal d31/g31 values.

TABLE 1

| | | PZT type | | | | |
|---|---|---|---|---|---|---|
| Feature | | 5K | 5H4E | 5B | 7A | 5A |
| Currie Temp. | ° C. | 160 | 230 | 330 | 350 | 365 |
| Dielectric | | 6,200 | 3,800 | 2,350 | 410 | 1900 |
| constant | | | | | | |
| d31 PE strain | pC/N | 370 | 320 | 210 | 60 | 180 |
| constant | | | | | | |
| g31 PE voltage | 10⁻³ | 6.8 | 9.5 | 10.1 | 16.8 | 10.6 |
| constant | VM/N | | | | | |
| d31/g31 | | 54 | 34 | 21 | 4 | 17 |
| Y@ short | | 6.8 | 6.2 | 6.8 | 9.4 | |
| Young's | | | | | | |
| Modulus | | | | | | |

One of methods increasing the capacitance (Cₒ) is by replacing a single piezoelectric layer, as described above, by several thinner layers that are connected in series thereby forming a “stack” of “n” parallel layers. If a piezoelectric element of thickness T is replaced by n layers each of thickness t, where t=T/n, and the n layers are wired in parallel, the resultant capacitance of the n layers may reach theoretically

Cₜ=C_{T}^{x} (T/t)²; where Cₜ and C_{T} are the capacities of layers at thickness t and T respectively. Practically, when “t” is reduced to very low thickness of few microns, typically of 10-15 micron, as is the preferred case of the current invention, the extra thicknesses contributed by the electrodes and mostly by the adhesive material, combining the parallel layers may reduce “n” (n=T/t) by about 10%. Nevertheless, it is the scope of the current invention to utilize this feature to receive maximal electrical capacitance and maximal energy Eₒ. The current invention relates to a piezoelectric mono-block, or other type of piezoelectric bending cantilever made of two stacks, each stack comprised of n parallel layers, typically t=10-15 microns while the value of n is preferably, but not limited to, 3-5. All layers within the stack are polarized in the same direction and each of the two stacks comprising the mono-block is attached to the other in such a manner that while applying voltage across each of the stacks, one stack contracts while the other extends thereby resulting in flexing of the mono-block. The same mechanism is being effective when flexing the free tip of the mono-block and generating the voltage. In case an inactive vane/substrate is used, a single piezoelectric stack may be used.

As discussed above each of the stacks may be connected either in series or in parallel. The series bimorph element has one-fourth the capacitance and twice the voltage of the parallel element. Also, the series element has four times the impedance of the parallel element. While according to mathematics, both the series and parallel connections bear same instantaneous energy at OCV, marked differences between the series and parallel designs may be observed in the practical utilization of the energy generated by piezoelectric elements. It is the scope of the current invention to disclose that for the specific applications of activation of the piezoelectric bending cantilever element by an in-body organ like the heart, where low frequencies and low deflecting force are imposed and have to be met, the performance of the series connection is superior to the parallel. The superior performance of the series-connected element results from two mutually interrelated factors: (a) the fact that Vₒ is proportional to the flexing force, and the series connection provides a higher voltage at a given activation force that is preferred since the basic target of the invention is to achieve maximal efficiency with minimal activation force and (b) considering a single vibration, it can be shown mathematically that maximal power extraction for a particular application occurs when the piezoelectric element delivers the required charging voltage at one half its OCV. An equivalent condition is that initial displacement be applied such that the piezoelectric OCV is twice the charging voltage of the energy storage unit. However, practically, when an initial displacement is applied to the piezoelectric element and electric power is generated by this initial displacement, the displacement thereafter is repeated in subsequent free vibrations. Thus, any subsequent free vibrations which are generated as a result of the initial displacement, a portion of the mechanical energy supplied to the piezoelectric element by the initial displacement is repeatedly converted into electrical energy during each vibration. Therefore, in comparison with the case of a kinetic activation in which subsequent free vibrations do not occur, in the case of inertial activation, the mechanical energy can be converted into electrical energy with a higher degree of efficiency. During these subsequent free vibrations, the displacement of the piezoelectric element gradually decreases after each vibration, and the unloaded voltage (OCV) corresponding to this displacement gradually decreases. For this reason, in order to generate electric power more efficiently utilizing the succeeding free vibrations resulting from an initial displacement, it is preferable that the piezoelectric OCV be higher than the above-described voltage related to a single deflection mode. The series connection is one of the disclosed means that enable the achievement of high efficiency with minimal activation force. Therefore, one of the means disclosed above is related to free vibrations, through which mechanical energy is repeatedly converted into electrical energy from the vibrator so as to generate power efficiently.

The electro-mechanical coupling coefficient of a piezoelectric element is in general small and accordingly the ratio of the applied mechanical energy which is converted into electrical energy during any one displacement of the piezoelectric element is also relatively small. Ideally, the resonant frequency should be close to the expected input frequencies. This is not always the case. Sometimes it is hard to design a generator to meet the specification. The current invention overcomes this difficulty by utilizing a piezoelectric cantilever element of low stiffness. This is achieved by the use of thin layers which provide also the benefit of higher capacitance, thereby further increasing the energy. In general, the resonant frequency of any spring/mass system is a function of its stiffness and effective mass. Thus, when referring to the activation force, self- or resonant frequency, piezoelectric stiffness is an important parameter. According to the current invention, the stiffness is minimized by using layers of minimal thickness, making use of the mono-block design, such that the use of an inert, inactive vane that increases the stiffness is avoided. The low stiffness obtained by this design serves to bring the resonant frequency of the piezoelectric element into the frequency range of body organs, while concomitantly beneficially increasing capacitance.

As discussed above, bending or deflection of the piezoelectric cantilever element places one of the ceramic layers under tension and the other layer under compression. As a result of the induced stresses, the element generates an output voltage that is proportional to the applied force. However, while reducing the thickness of the piezoelectric layer, upon bending the cantilever the strain per layer decreases accordingly, consequently resulting in a smaller Vo. Increasing the Vo through increased deflection imposes greater force which is in conflict of the basics disclosed in this invention. Current invention overcomes this drawback by implementing the series connection of the piezoelectric mono-block.

In power generation systems utilizing cantilever piezoelectric elements, the mechanical activation originates from an external mechanical vibration or movement. The externally driven movement needs to be aligned with the deforming direction of the piezoelectric element. Efficient harnessing of the external motion by the piezoelectric cantilever cannot be achieved when the vector of the external motion is misaligned with the deforming direction of the piezoelectric element. Since orientation of the externally driven vibration may occasionally change with respect to the orientation of the originally installed, firm orientation of the piezoelectric element within the enclosure, the effectiveness of the harnessing of the motion may vary, and may go all the way down to zero. An even more complex problem arises from the presence of two independent forces or movements, such as the movement of a body organ or other object to which the piezoelectric generator is attached and its orientation in the gravitational field.

The present invention provides a solution to the above outlined problems—to align the bending vector of the piezoelectric cantilever with the vectors of the external vibration or movement and the direction of the gravitational field. The invention provides a method to get efficient power generation which is independent of the direction of the externally driven vibration.

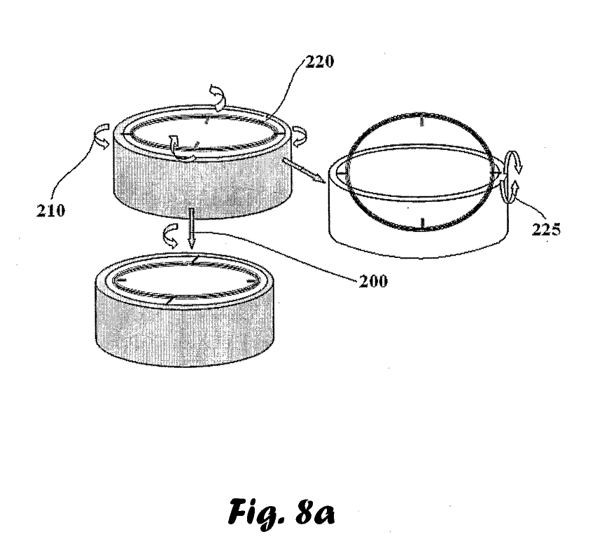

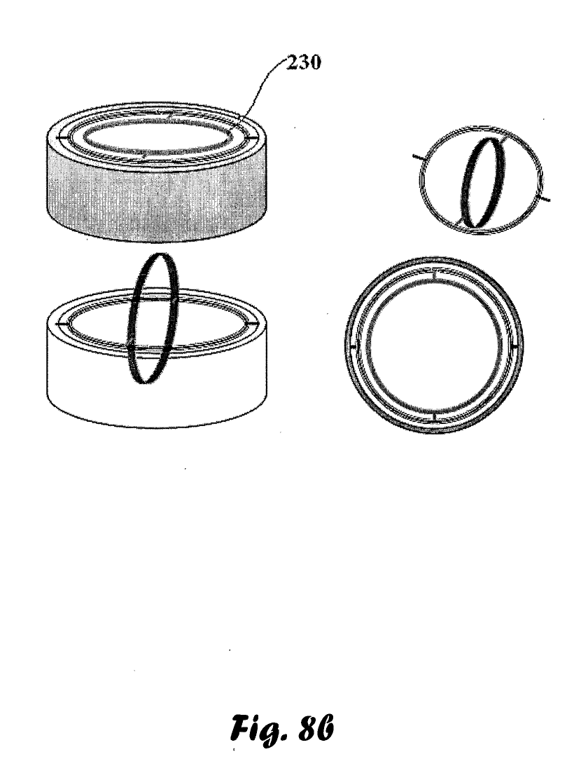

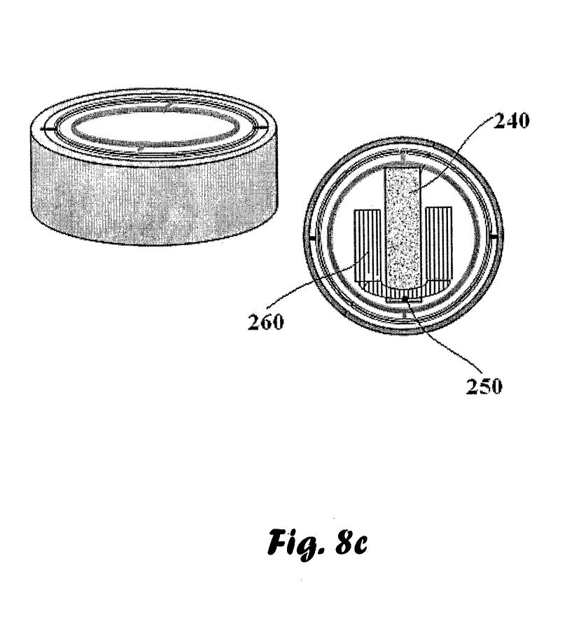

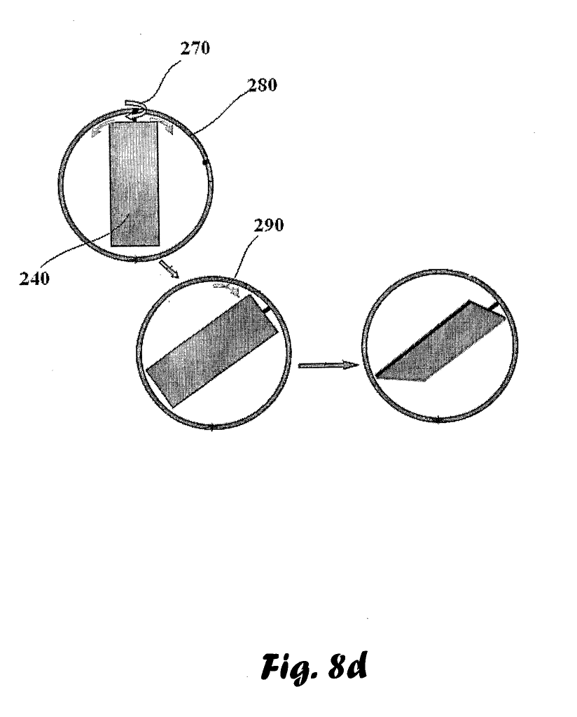

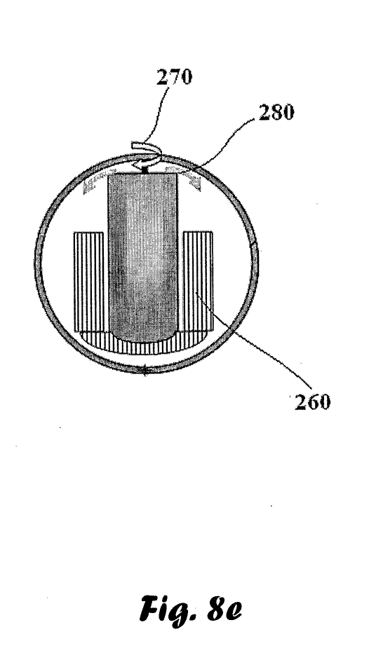

Reference is now made to FIGS. 8a-e, which present diagrams characterizing of operation mode 3-D harnessing mechanism. The figures illustrate the methods of installing the piezoelectric element within the enclosure as to enable harnessing the inertial energy of the motion, regardless of the orientation of the enclosure relative to the moving body and to gravitation.

FIG. 8a depicts rotational motion of an external ring 220 around an axis 225, rotational and linear motions 210 and 200, respectively. FIG. 8b presents rotational motion of a n internal ring 230. FIG. 8c presents a piezoelectric element 240 provided at a flexing end 250 with a PCB device 260 adapted for energy storage and control. The device 260 comprises a ballast weigh (not shown) activated by external motion. FIGS. 8d and 8e depict rotational motions 270 and 290 of the element 240 fixed to the ring 280.

The advantage of the design is utilization of maximal length and width of the piezoelectric element, within a fixed volume, thereby providing maximal power output for a given fixed volume enclosure.

Another option to harness the external motion, independently of its' orientation, is installing multiple piezoelectric cantilevers within the enclosure, in such a manner that whatever the orientation of the external motion is, its vector shall coincide with the bending orientation of one or several piezoelectric elements.

In summary, the current invention discloses a method for generating maximal power while overcoming the following difficulties:

a) low-amplitude activation forces;

b) low activation frequencies;

c) restricted volume available; and

d) variable orientation of the external vibration or motion and the gravitational field with respect to the bending direction of the piezoelectric element.

The above outlined operational parameters normally cause very low power output due to inefficient harnessing of the motion, followed by small deflection of the piezoelectric cantilever. The current invention addresses the problems by using thin multilayer stacks, the mono-block design and the series connection of the piezoelectric stacks, while ensuring efficient harnessing of the motion by introduction of the 3-D harnessing mechanism as discussed and illustrated above.

Power Control and Energy Storage Unit

In practical applications, it's important to fully exploit the available energy of the piezoelectric element. Maximal piezoelectric electrical energy has shown in equation (7) above:

Eₒ=½ CV₀²; (7)

where Eₒ is the maximal generated energy through the mechanical deformation of the piezoelectric element at Open Circuit Voltage (OCV) conditions, OCV meaning that no current/energy is withdrawn from the piezoelectric element(s); C is the piezoelectric capacitance and V₀ is the instantaneous OCV at deformation/deflection ΔX.

It should be noted that self-vibration of the cantilever within the interval of externally enforced displacements (the original frequency of the body imposing the motion), though undergoing continuous damping, may still contribute considerable extra energy.

The piezoelectric cantilever exhibits self vibrations within the interval of the externally imposed (forced) frequency. To achieve maximal transformation of the piezoelectric energy at OCV to available energy (utilized to charge the energy storage unit), it is important to adjust the voltage value and the interval during which the piezoelectric is connected to the parallel energy storage unit. Extraction of this potentially available energy depends on matching the piezoelectric Voltage and its' self-vibration frequency with the charging voltage of the coupled energy storage unit. The voltage control and switching is conducted by the power control unit by coupling the piezoelectric element to the energy storage unit.

The piezoelectric element is connected to the energy storage unit through a power management element. The function of the power management element is rectifying the AC voltage of the piezoelectric to DC voltage, and at the same time switching the connection of the piezoelectric element and the distinct energy storage units according to the changing voltage values of the piezoelectric element and the properties of individual energy storage units.

A variety of patents and literature refer to the method the piezoelectric energy is delivered to a parallel connected capacitor or rechargeable battery charged by the piezoelectric element and used to store the energy to be delivered upon demand. However, none of these publications makes a clear distinction between the capacitor and the battery in respect how each storage technology affects the conversion efficiency. Nevertheless, there is an inherent difference between the two, having a marked effect on efficiency, when transferring energy from the piezoelectric to charge a capacitor or to charge a battery. The current invention claims that for lightweight and small size devices use of a capacitor with specific value, to be discussed herein, provides considerable advantage over the use of a battery:
(a) Batteries contain active chemical materials and hence their enclosure constitute substantial portion of their weight and volume
(b) With miniature size batteries the passive components comprising the battery, like the case, constitute considerable fraction of weight and volume resulting in a sizeable decrease in the gravimetric and volumetric specific energies.
(c) The equivalent serial resistance (ESR) of miniature batteries is relatively high leading to very small power density.
(d) Any rechargeable battery system bears its very specific charging voltage within a specified and narrow voltage range. Since matching of the piezoelectric voltage and the charging voltage is of critical importance to achieve maximal efficiency, the fact that a battery imposes very specific condition for the charging voltage makes it very difficult to optimize the mechanical design parameters of the piezoelectric element which have to be optimized on one hand to the mechanical activation as to attain maximal conversion efficiency within the specific limitations of the application: minimal activation force and minimal footprint, and on the other hand to deliver the proper charging voltage to the battery. All of commercial rechargeable batteries require charging voltage >1.4V for aqueous systems and >3V for organic, lithium based systems. Thus in the case of using battery as the energy storage element the design of the piezoelectric element should meet these constraints or a proper DC converter should be used, in both cases imposing design parameters on the piezoelectric element that may be far from optimal for the mechanical conversion efficiency.

As discussed above, the piezoelectric generator of the current invention refers to piezoelectric elements of minimal thickness providing maximal capacitance and at the same time enables activation by minimal force. However these design parameters impose relatively low OCV of the piezoelectric element. As discussed above, for optimal delivery of energy from the piezoelectric to the storage unit, the charging voltage of the storage unit should be no more than half (½) of the piezoelectric OCV. Thus it becomes clear that unless using an extra voltage converting element to ramp-up the Piezoelectric output to the charging voltage of the battery, the voltage of piezoelectric elements with OCV of <1.4V is not applicable at all while for effective charging the piezoelectric OCV should be ˜3V for aqueous battery systems and 7-8 V for organic, lithium battery systems. Reviewing the formulae of piezoelectric voltage and the relation of displacement-voltage-force, it becomes obvious that piezoelectric elements designed to meet the charging voltage of the batteries are far from the optimal parameters meeting the operating conditions set-forth in current application, it means minimal activation force at minimal footprint.

In contrast to batteries, the properties of capacitors are not dictated by a specific chemistry, and capacitors may be chosen at any capacitance and within any voltage range suitable to the task. Furthermore, the charging voltage of capacitors is linear starting from zero, which, unlike batteries that require a specific charging voltage, allows direct energy extraction at any charge-state of the piezoelectric element. Also state-of-the-art polymer capacitors like Al or mostly preferred Ta, or any other composition, are available at miniature size and at light weight, not exceeding the weight of tens of milligrams. Also, the ESR of these small size capacitors is very low, in the milli-Ohm range, as opposed to the small size batteries bearing ESR of tens to hundreds Ohms. The low ESR of the capacitor reduces considerably the resistance-capacitance (RC), thereby shorting the time through which the charge flows from the piezoelectric to the capacitor contributing to higher transformation efficiency. As discussed, vibration damping of charged piezoelectric at OCV is greater than short-circuited. Self-vibration of the piezoelectric element within the period between displacements enforced by the external motion has a considerable contribution to the transformation efficiency. Thus to extend the self-vibration, or flexing of the piezoelectric element, not only the stiffness of the piezoelectric should be minimized as to reduce the mechanical damping, but also the rate at which the charge is delivered from the piezoelectric to the energy storage capacitor. This is related to minimal RC of the capacitor and the ΔV between the piezoelectric and the capacitor at charge. By using the architecture as disclosed in current invention, maximal optimization can be achieved.

As discussed above, one of basic principles implemented in the generator design is utilizing thin-layer piezoelectric elements enabling small activation force, large piezoelectric capacitance and low damping factor. However, while this design provides clear benefits, it has a concomitant disadvantage in the relatively low voltage generated by the piezoelectric element. The current invention resolves this problem by making use of several independent capacitors, each charged to a low voltage which may be in any desired range. For miniature systems these values are typically between 0.1-2 V. Each of the capacitors is connected independently to the power management unit that switches among the individual capacitors and the piezoelectric element.

Also, it should be considered that greater voltage difference between the piezoelectric and the capacitor shortens the time during which the current flows from the piezoelectric to the energy storage element. If the energy storage capacitance is small, the voltage will go up quickly, limiting the time the current flows and making it practically impossible to optimize the voltage ratios of the piezoelectric and the charged capacitor. However, if the capacitance is large it takes time for the voltage to build up and allows the current to flow for more time. Thus for maximal transformation efficiency the piezoelectric voltage, the capacitance and the frequency should be matched. The current approach enables maintaining optimal voltage difference between the piezoelectric and the individual capacitor at charge and its adjustment to the frequency.

On the output side, the combination of individual capacitors enables also to avoid the use of a DC-DC converter, commonly used in many applications at the voltage input and output. The same or a separate power management element controls also the voltage that has to be delivered to the external load. By connecting in series the individual capacitors voltage ramp-up at output is possible. Connecting in parallel the capacitors enables delivery of relatively high charge (Q=I*t). By using a power management element and several individual capacitors, decoupling of the piezoelectric element and the energy storage unit is achieved. This design enables independent charging and discharging of separate capacitors thereby achieving optimal operation conditions for either the charge or the discharge mode.

Another built-in operational concept is maintaining the voltage of each capacitor at relatively constant value matched to the piezoelectric voltage. This can be easily achieved by using the voltage control and switching power management element and periodically coupling the piezoelectric element to individual capacitors. Typical capacitance of piezoelectric cantilever mono-block bimorph element of 20 mm×8 mm×0.15 mm is about 1 micro-Farad. Such a bi-morph contains two series connected stacks, each stack comprising five parallel layers of about 15 microns thickness, resulting at 0.4 μF per layer or about 2 μF per stack. At series connection of the two stacks the resultant capacitance is 1 μF.

Such a piezoelectric element is being coupled, through the power management unit with several, at least two, Ta (or other) solid state capacitors. Since for medical applications the operation temperature doesn't extend 37-42° C., no significant voltage de-rating is required to maintain a long service life. It is also well known to one skilled in the area, that maximal capacitance per unit volume or weight is achieved with capacitors operating at the low range of voltage. Thus very small capacitors with maximal specific capacitance may be used. Typical Ta sintered anode designed to operate at 2-6.3V and 85° C. provides 250-300 mFV/c.c. or 30-35 mFV/gr. Thus Ta anode pellet of 2-3V operating voltage and 220 μF will occupy 0.0015-0.0027 cc and weigh 12-23 milligram. Typical chip capacitor composed of polymer conductive counter electrode and enclosed within epoxy potting will occupy 0.002-0.003 cc and weight 20-30 milligram including termination. Thus even upon utilization of ten (10) individual capacitors the total volume and weight will not exceed 0.03 cc/0.3 gram respectively, while providing inherent advantage of charging each individual capacitor at preset voltage matched to the voltage supplied by the piezoelectric element.

Since the ratio of the piezoelectric capacitor to the storage capacitor is at most 1:220 (<0.5%) and the intended vibration frequency is typically low, the rate of voltage rise upon charging the storage capacitor is relatively slow thereby making it simple to control the voltage of each storage capacitor within a relatively narrow range matching the voltage of the piezoelectric element. Also upon power delivery, the power management unit switches in series or parallel the individual capacitors as to control the voltage drop of each capacitor within a typical limit of <20% as to maintain the voltage of the capacitor for subsequent charging within the range of optimal ratio of piezoelectric and charging voltage. For instance, utilizing ten 2V/220 μF capacitors and maintaining their voltage within the range of 1.2V as the charge limit and 0.8V as the discharge limit, fits well to piezoelectric voltage of 2-3V in respect to optimal transformation efficiency of electrical energy between the piezoelectric and the storage capacitors on one hand, and for optimal conversion efficiency of the mechanical energy to electrical energy generated by the piezoelectric operated at the set-forth conditions of minimal stiffness, minimal size, etc. The same architecture of the ten capacitors may be charged/discharged within the range of 2.2V to 1.8V and coupled with piezoelectric generating 4-6V. It should be noted that instead of storage capacitor of 2-3V/220 μF, several capacitors of 2-3V/1 mF may be used and switched in same manner and according to same principles as described above. As mentioned, since the ESR of the Ta chip capacitors is relatively low, staying <1Ω even at series connection of several capacitors, no voltage drop upon pulse delivery or RC caused holdup of charging or discharging occurs. In this scheme, each capacitor may be kept at a different voltage value so as to match the variable voltage output of the piezoelectric generator.

According to one design of the invention a number of capacitors of different charging voltage and capacitance are used so as to match the variable voltage output of the piezoelectric generator and provide more efficient charging under highly variable charging conditions and to provide further flexibility in output pulse delivery.

During the damping period of the piezoelectric element, the voltage generated due to the self-vibrations of the piezoelectric element undergoes continuous decay. By implementing an array of independent capacitors, the piezoelectric element may be connected trough the power management unit to individual capacitors, each maintained within a specific and relatively narrow voltage range so as to match the decaying piezoelectric voltage to a capacitor at ½ the voltage value of the piezoelectric element.

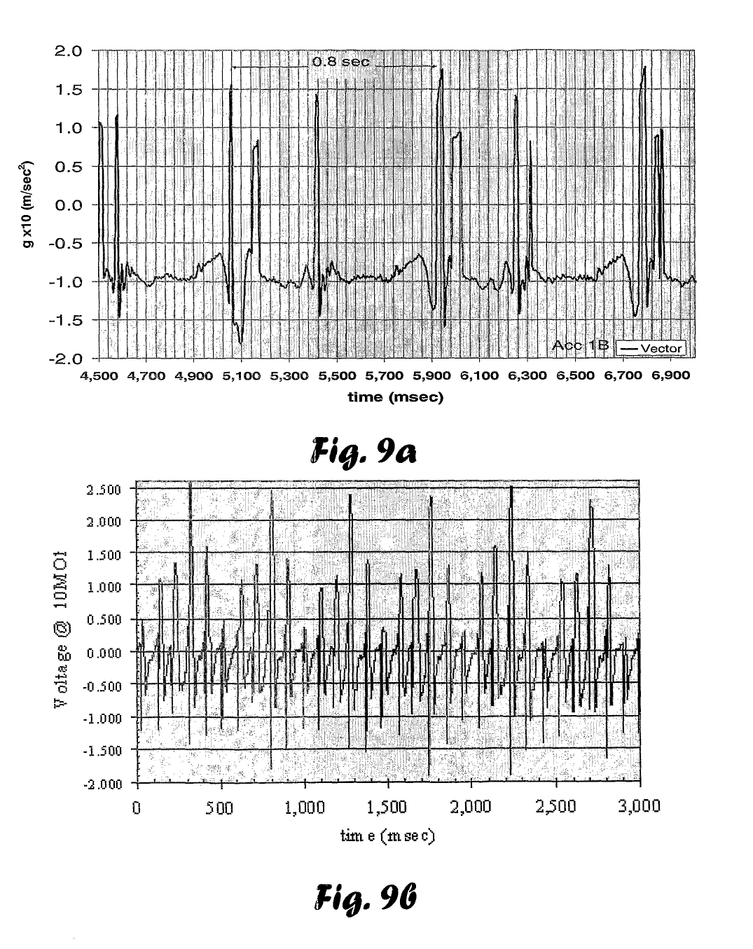

Reference is now made to FIGS. 9a and 9b time curves of the cardiac acceleration and the piezoelectrically generated voltage due to picking up the energy of cardiac contraction. It is shown that a train of non-rhythmic cardiac contractions is converted into a rhythmic train of voltage pulses. It should be appreciated that the rhythmicity of voltage pulses is achieved due to resonant properties of the piezoelectric element provided with the mechanical harnessing unit.

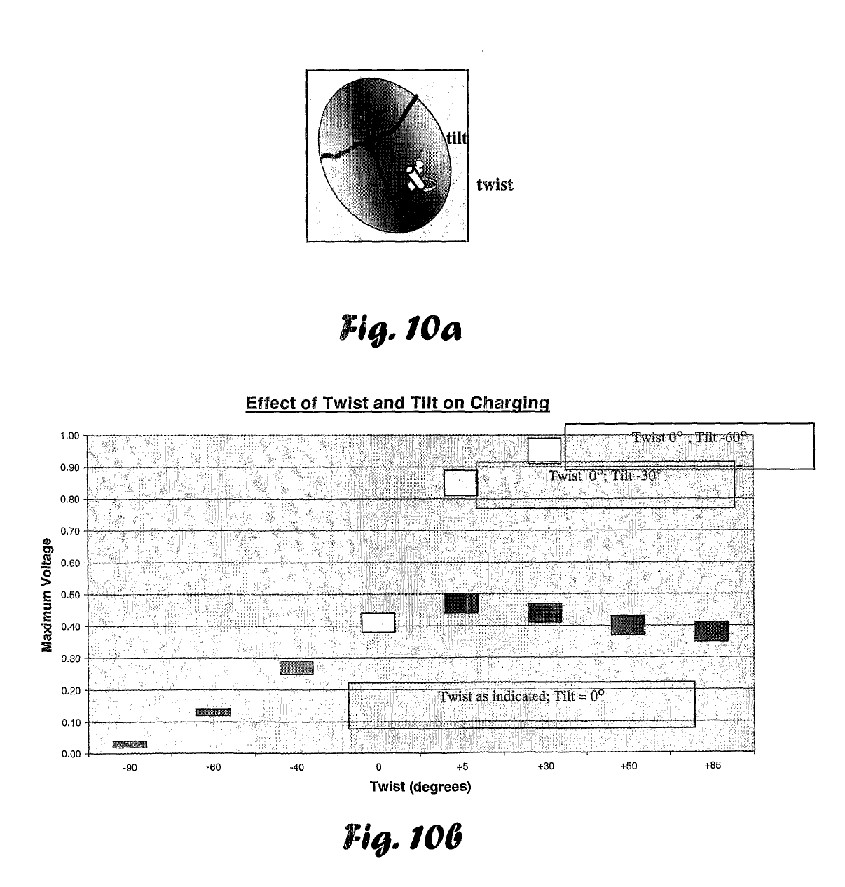

Reference is now made to FIGS. 10a and 10b, presenting a geometric scheme of the micro-generator orientation relative to the heart; and a graph of the generated voltage in dependence on the geometric orientation, respectively. It is shown that the generated voltage depends on the geometric orientation.

1. A power supply for implanting into a patient's body and providing electricity to a load within said body, said power supply comprising an enclosure; adapted for optimizing an activating force by means of orienting thereof; said power supply further comprising
(a) a piezoelectric micro-generator comprising
(i) a piezoelectric element/having an elongate shape with first and second terminals; said first terminal mechanically connected to said enclosure; said piezoelectric element configured for substantially resonant oscillation at frequency characterizing motion of said patient's heart or other organ;
(ii) a mechanical harnessing unit mechanically connected to said second terminal of said piezoelectric element to increase an oscillation amplitude of said piezoelectric element;
(b) electrical energy storing means;
(c) control unit adapted for managing charging and discharging said storing means said control unit further provided with means for decoupling said piezoelectric element from and connecting to said electrical energy storing means to increase efficiency of said power supply.

2. The generator according to claim 1, wherein said piezoelectric element is configured as a laterally bending cantilever.

3. The generator according to claim 1 further comprising a power control unit adapted to effectively convert electrical oscillations of ultralow frequency created in said piezoelectric element between activation events.

4. The generator according to claim 3, wherein said power control unit is adapted to compensate the beat to beat variation in frequency and activation force.

5. The generator according to claim 3, wherein said power control unit is adapted to accumulate energy of activation impulses independently on repetition rate thereof.

6. The generator according to claim 3, wherein said the power control unit is adapted to perform at least one function selected from the group consisting of voltage rectification, charging said storage unit, providing stored electricity to said load, switching, controlling and any combination thereof.

7. The generator according to claim 3, wherein said electric energy storing comprises an array of storing elements.

8. The generator according to claim 1, wherein said electric energy storing comprises at least one capacitor.

9. The generator according to claim 1, wherein said electric energy storing comprises at least one rechargeable battery.

10. The generator according to claim 1, wherein said piezoelectric element is configured for substantially resonant oscillation with a frequency ranged between about 1 and 3 Hz.

11. The generator according to claim 1, wherein said piezoelectric element is made of PZT ceramics.

12. The generator according to claim 1, wherein said piezoelectric element is configured as a multilayer structure (a piezoelectric stack).

13. The generator according to claim 1, wherein said piezoelectric stack comprises at least one inactive layer adapted to optimize elastic property of said stack.

14. The generator according to claim 1, wherein said piezoelectric element is disposed a holder which is adapted for linear displacement along an axis of said piezoelectric element, angular displacements of around said axis of said piezoelectric element and in a plane of said piezoelectric element to orient said piezoelectric element perpendicularly to an activating force.

15. A method of piezoelectric conversion of a patient's body motion into electric energy, said method comprising the steps of:
(a) providing a micro-generator further comprising
i. a enclosure; and
ii. a piezoelectric element having an elongate shape with first and second terminals; said first terminal mechanically connected to said enclosure; said piezoelectric element configured for substantially resonant oscillation at frequency characterizing motion of said patient's body; and
iii. an electric energy storing means;
(b) implanting into the patient's body;
(c) inertially picking up mechanical energy of body motion;
wherein said step of picking up mechanical energy is performed by said piezoelectric element provided at said second terminal with an mechanical harnessing unit to increase an oscillation amplitude of said piezoelectric element.

16. The method according to claim 15 further comprising a step of effectively converting electrical oscillations of ultralow frequency created in said piezoelectric element between activation events.

17. The method according to claim 15 further comprising a step of compensating the beat to beat variation in frequency and activation force.

18. The method according to claim 15 further comprising a step of accumulate energy of activation impulses independently on repetition rate thereof.

19. The method according to claim 15 further comprising a step of performing at least one function selected from the group consisting of voltage rectification, charging said storage unit, providing stored electricity to said load and any combination thereof.

20. The method according to claim 15 further comprising a step of linearly displacing said piezoelectric element along an axis thereof, angularly displacing of around said axis of said piezoelectric element and in a plane of said piezoelectric element to orient said piezoelectric element perpendicularly to an activating force.
